(19) United States
(12) Patent Application Publication
(10) Pub. No.: US 2023/0054963 A1
(43) Pub. Date: Feb. 23, 2023

(54) INTEGRATED CIRCUIT HAVING MICRO-ETCHED CHANNELS

(71) Applicant: TEXAS INSTRUMENTS INCORPORATED, DALLAS, TX (US)

(72) Inventors: Dolores Babaran Milo, Baguio City (PH); Michael Flores Milo, Baguio City (PH)

(21) Appl. No.: 17/405,125

(22) Filed: Aug. 18, 2021

(51) Int. Cl. H01L 23/495; H01L 23/31

(52) U.S. Cl. CPC H01L 23/49503; H01L 23/31; H01L 23/49541; H01L 23/49575

(57) ABSTRACT

An integrated circuit that includes micro-etched channels on a bottom surface is provided. The integrated circuit includes a lead frame having electrically conductive contact terminal pads and a die centrally disposed in the lead frame. Wire bonds provide an electrical connection from the die to the electrically conductive contact terminal pads. A mold compound encapsulates the die and the wire bonds, where a bottom surface of the mold compound is flush with a bottom surface of the contact terminal pads. A channel is defined in the bottom surface of the mold compound around a periphery of the contact terminal pads.

### TECHNICAL FIELD

The present disclosure relates generally to integrated circuits, and more specifically to an integrated circuit having micro-etched channels on a bottom surface of the integrated circuit.

### BACKGROUND

Quad flat no-lead (QFN) packages are an integrated circuit (IC) package technology that provide an electrical connection between the integrated circuit and a printed circuit board (PCB). QFN packages require a die (e.g., silicon die) and a lead-frame to house electrical terminations that connect to the PCB. In addition, electrically conductive connecting wires are required to provide an electrical connection from the die to the lead frame. The lead frame carries signals from the die outside the QFN package to the printed circuit board. The lead frame includes a thermal pad (die attach pad) that facilitates the dissipation of heat.

### SUMMARY

In described examples, an integrated circuit includes a lead frame having electrically conductive contact terminal pads and a die centrally disposed in the lead frame. Wire bonds provide an electrical connection from the die to the electrically conductive terminal pads. A mold compound encapsulates the die and the wire bonds, where a bottom surface of the mold compound is flush with a bottom surface of the contact terminal pads. A channel is defined in the bottom surface of the mold compound around a periphery of the contact terminal pads.

In another described example, an electronic device assembly includes a printed circuit board (PCB) and an integrated circuit attached to the PCB. The integrated circuit includes a lead frame having electrically conductive contact terminal pads and a die centrally disposed in the lead frame. Wire bonds provide an electrical connection from the die to the electrically conductive terminal pads. A mold compound encapsulates the die and the wire bonds, where a bottom surface of the mold compound is flush with a bottom surface of the contact terminal pads. A channel is defined in the bottom surface of the mold compound around a periphery of the contact terminal pads. An under-fill material is disposed between the bottom surface of the mold compound and a top surface of the PCB, wherein the under-fill material is disposed in the channels.

In another described example, a method of fabricating integrated circuits includes providing a lead frame having leads and a die pad, the die pad being centrally disposed in the lead frame and attaching a die to a top planar surface of the die pad via a die attach. Wire bonds are attached from the die to the leads. A mold compound is formed over the lead frame, the die, and the wire bonds to form an integrated circuit, the leads having contact terminal pads exposed on a bottom surface of the mold compound where the contact terminal pads are substantially flush with the bottom surface of the mold compound. A channel is etched on the bottom surface of the mold compound and around a periphery of the contact terminal pads, wherein the channels configured to receive an under-fill material.

### BRIEF DESCRIPTION OF THE DRAWINGS

FIGS. 1 and 2 are side and lead side views respectively of an example electronic device assembly that incorporates micro-etched channels and under-fill material.

FIG. 3 is a bottom view of an example integrated circuit (IC) package illustrated in FIGS. 1 and 2.

FIG. 4 is a cross section view of the example IC package taken along line A-A in FIG. 3.

FIG. 5 is a side view of an example QFN package that does not incorporate the micro-etched channels and the under-fill material.

FIG. 6 is a close-up view of a lead of the example QFN package of FIG. 5 soldered to a printed circuit board pad.

FIG. 7 is a flow diagram for a method of fabricating the electronic device and IC package of FIGS. 1 and 2.

### DETAILED DESCRIPTION

Disclosed herein is an example integrated circuit (IC) (e.g., Quad Flat No-Lead (QFN)) package configured to reduce solder fatigue and to compensate for a Coefficient of Thermal Expansion (CTE) mismatch between the IC package and a printed circuit board (PCB). IC packages such as the QFN package are prone to solder fatigue and cracking caused by a high coefficient of thermal expansion (CTE) mismatch between the IC package and the PCB. In addition, solder fatigue and cracking is also facilitated by the lack of flexibility between leads in a lead frame and the IC body of the QFN package since the leads of the lead frame are embedded in the IC body. Thus, QFN packages have a higher risk of board level reliability (BLR) fails as compared to other IC packages (e.g., DIP, SOP, QFP, etc.) where the leads flex independent of the IC body.

The example IC package includes micro-etched channels etched into a bottom of the IC package around a periphery of contact terminal pads. After the IC package is mounted to the PCB an under-fill is injected between the bottom of the IC package and the PCB. During the injection process, the under-fill fills the micro-etched channels. The under-fill material is a flexible material that makes a bond between the IC package and the PCB stronger. In addition, the under-fill material distributes the stress more evenly between the IC package and the PCB, which in turn reduces the stress between the lead frame and the PCB where fatigue typically occurs.

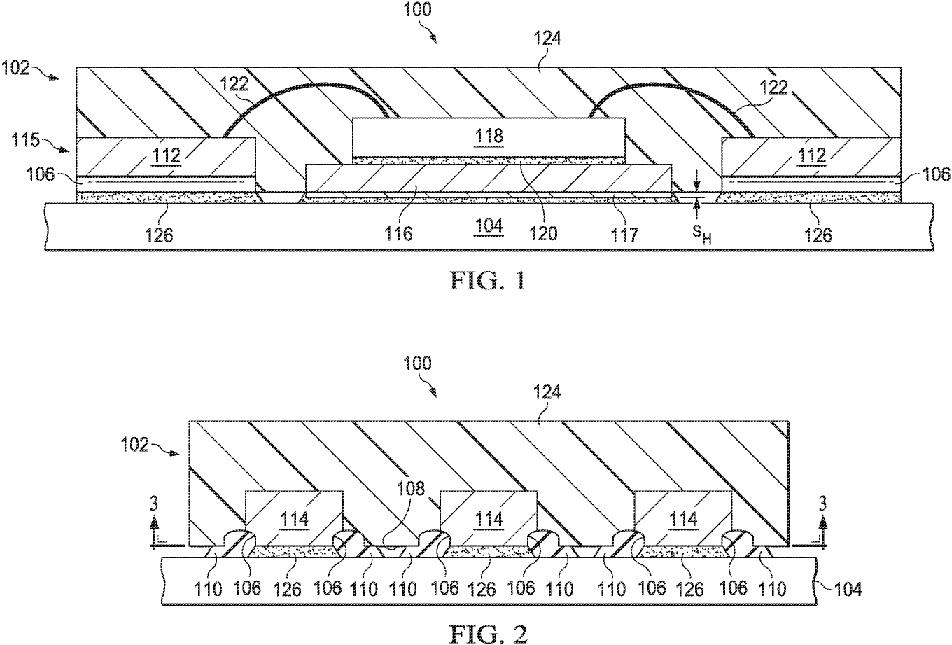

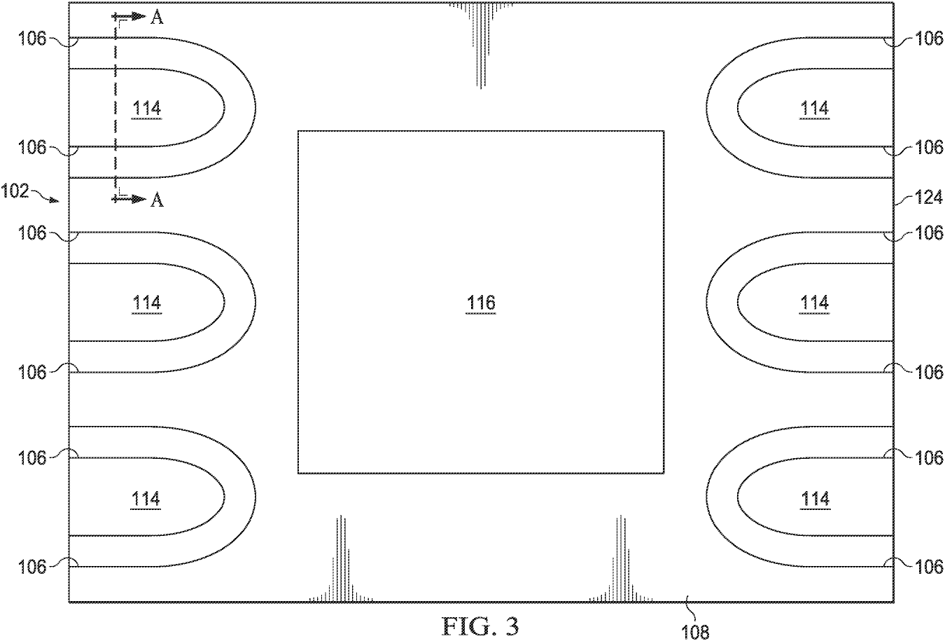

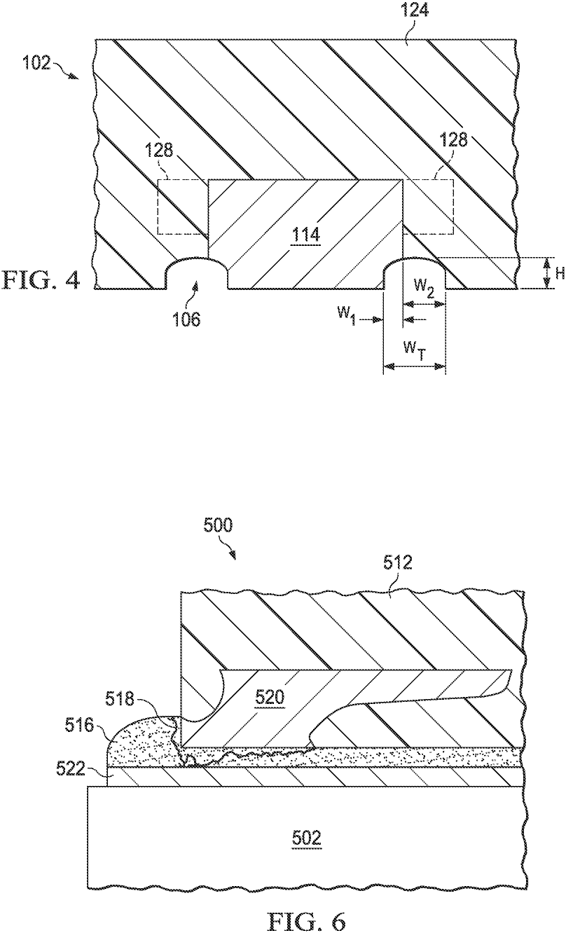

FIGS. 1 and 2 are side and lead side views respectively of an electronic device assembly 100 that includes an example integrated circuit (IC) (e.g., Quad Flat No-Lead (QFN)) package 102 mounted to a printed circuit board (PCB) 104. FIG. 3 is a bottom view of the IC package 102 and FIG. 4 is a cross section view of the IC package 102 taken along line A-A in FIG. 3. The IC package 102 is configured to reduce solder fatigue. Specifically, the configuration of the IC package 102 includes micro-etched channels 106 etched via an etching process (e.g., laser ablation) into a bottom surface 108 of the IC package 102. The micro-etched channels 106 receive an under-fill material 110 (e.g., silica, epoxy) during the assembly process of the IC package 102 to the PCB 104. The under-fill material 110 is a flexible material and uniformly distributes stresses between the IC package 102 and the PCB 104 thereby reducing solder fatigue between the IC package 102 and the PCB 104. The under-fill material 110 also compensates for a Coefficient of Thermal Expansion (CTE) mismatch between the IC package 102 and the PCB 104, which reduces cracking at a solder joint (see FIG. 6) and improves reliability performance of the electronic device 100.

In order to facilitate the flow of the under-fill material 110 between the IC package 102 and the PCB 104, a solder stand-off height S_{H} between the bottom surface 108 of the IC package 102 and the PCB 104 is increased to allow the flow of the under-fill material 110 into the channels 106. In one example, the solder stand-off height S_{H} is approximately 50-75um.

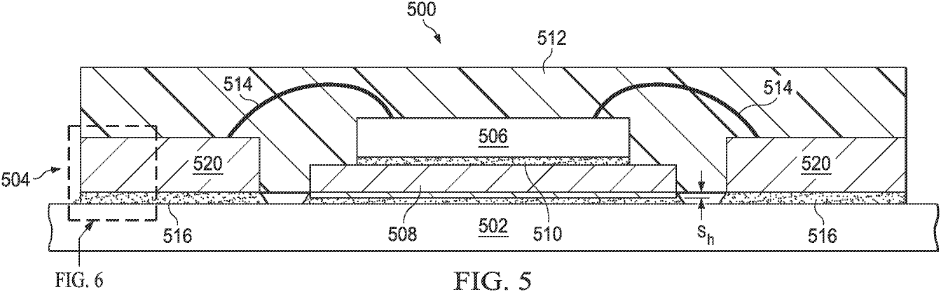

Comparably, QFN IC packages 500 such as the one illustrated in FIGS. 5 and 6 that do not incorporate the micro-etched channels have a smaller solder stand-off height Sₕ of approximately 0-50um between the bottom of the IC package 500 and a PCB 502. FIG. 5 is a side view of the QFN IC package 500 and FIG. 6 is a close-up view of a lead of the QFN IC package 500 soldered to the PCB 502 that does not incorporate the micro-etched channels and the under-fill material as disclosed herein. The QFN IC package 500 includes a lead frame 504 comprising leads 520 and a die pad 508, and die 506 attached to the die pad 508 via a die attach 510, which are encapsulated by a mold compound 512. Wire bonds 514 are connected from the die 506 to the leads 520. The QFN IC package 500 further includes contact terminal pads. Solder 516 is provided to electrically attach the QFN IC package 500 to the PCB 502. As mentioned above, these QFN IC packages 500 are prone to solder fatigue that leads to solder cracks 518 (see FIG. 6) in the solder 516. More specifically, solder cracks 518 form in a solder joint between the leads 520 of the lead frame 504 and a PCB pad 522 due to fatigue as described herein.

Referring back to FIGS. 1-4, the IC package 102 further includes a lead frame 115 comprising a die pad 116, leads 112, and exposed electrically conductive contact terminal pads 114. The contact terminal pads 114 may have an exposed surface on one or more sides (FIG. 2) of the IC package 102 and/or on the bottom surface 108 of the IC package 102 (FIG. 3). The die pad 116 is centrally disposed in the lead frame 115 and hence, the IC package 102. The die pad 116 includes an exposed pad 117 that is exposed on the bottom surface 108 of the IC package 102. The exposed pad 117 of the die pad 116 is thermally conductive and provides a heat path to the PCB 104 and/or may also provide a ground connection. The exposed pad 117 may or may not be flush with the bottom surface 108 of the IC package 102. A die 118 is centrally disposed in the lead frame 115 and hence the IC package 102 and is attached to a top planar surface of the die pad 116 via a die attach 120 (e.g., adhesive, paste, epoxy, thermally and/or electrically conductive bonding agent). The die 118 can be made from a semi-conductive material (e.g., silicon, gallium arsenide, etc.) and can include electronic components embedded therein thus, forming an integrated circuit. Wire bonds 122 provide an electrical connection between the die 118 and the leads 112. The wire bonds 122 can be attached to the die 118 and the leads 112 via thermosonic (heat and energy) bonding, ball (heat) bonding, compliant (heat and pressure) bonding, soldering, etc.

A mold compound 124 is formed over the lead frame 115, the die 118, the wire bonds 122, and the die pad 116 such that the mold compound 124 encapsulates the die 118 and the wire bonds 122. The exposed surfaces of the contact terminal pads 114, however, are substantially flush one or more sides of the mold compound 124 and/or on a bottom surface mold compound 124. The IC package 102 is attached to the PCB 104 via a soldering process. Specifically, solder paste 126 is evenly spread on the PCB 104 via solder paste printing process. After the IC package 102 is mounted on the PCB 104, the electronic device assembly 100 is passed through a reflow oven to heat the solder paste 126 to a predetermine temperature. The electronic device assembly 100 is then cooled to solidify the solder paste 126.

As illustrated in FIG. 4, the IC package 102 further includes lead locks 128. Specifically, inner leads of the lead frame 115 include lead locks 128 to increase a bonding force between the lead frame 115 and the mold compound 124 to effectively preventing a separation in a vertical and/or horizontal direction of the lead frame 115 from occurring in a singulation process during fabrication of the IC package 102.

FIG. 4 further illustrates approximate height H and width W_{T} dimensions of the micro-etched channels 106. The channels 106 are etched via an etching process such as for example by laser ablation into the bottom surface 108 of the IC package 102. Specifically, the channels 106 are etched into a bottom surface of the mold compound 124 and around a periphery of the contact terminal pads 114. A height H of the micro-etched channels 106 are approximately 40-50 um high. The etched height ensures that there is sufficient clearance between the channels 106 and the lead locks 128 described above. In addition, the etched height H of the channel 106 ensures that a sufficient amount of the under-fill material 110 flows into the channel 106.

A total width W_{T} of each channel 106 is approximately 55-75 um wide. A portion of the total width W_{T} of each channel 106 partially overlaps the contact terminal pads 114 and partially overlaps the mold compound 124. Specifically, a portion of the total width W_{T} of each channel 106 has a first width W₁ partially etched into the contact terminal pad 114 of the lead frame 115 approximately 15-25 um and a second width W₂ partially etched into the mold compound 124 approximately 40-50 um. As illustrated in FIG. 4 and as described herein, W₁ is less than W₂. The minimal partial etching into the contact terminal pad 114 provides enough surface area on the contact terminal pads 114 to allow proper adhesion to the PCB 104 during a solder wetting process and also minimizes any negative effects during electrical testing of the electronic device assembly 100.

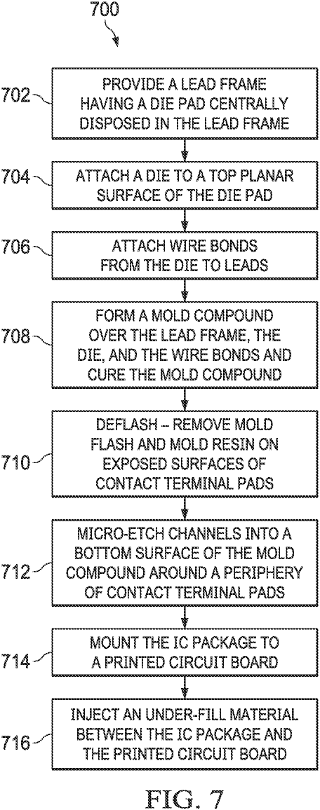

FIG. 7 illustrates a fabrication flow diagram 700 illustrating a fabricating process in connection with the electronic device assembly 100 and the IC package 102 illustrated in FIGS. 1-4. Though depicted sequentially as a matter of convenience, at least some of the actions shown can be performed in a different order and/or performed in parallel. Alternatively, some implementations may perform only some of the actions shown. Still further, although the example illustrated in FIG. 7 is an example method illustrating the example configuration of FIGS. 1-4, other methods and configurations are possible.

At 702, a lead frame (e.g., lead frame 115) including a die pad (e.g., die pad 116) are provided where the die pad is centrally disposed in the lead frame. At 704, a die (e.g., die 118) is attached to a top planar surface of the die pad via a die attach (e.g., die attach 120). At 706, wire bonds (e.g., wire bonds 122) are attached to the die via a bump bond or soldering process and to the leads (e.g., leads 112) frame via a bump bond or soldering process. At 708, a mold compound (e.g., mold compound 124.) is formed over the lead frame, the die, the die attach, the wire bonds, and the die pad and cured during a curing process. The mold compound is formed such that the mold compound encapsulates the die, the wire bonds, and the die attach. The mold compound can be made from an epoxy or epoxy blends, silicone, polyimide, etc. At 710, mold flash and mold resin are removed from exposed surfaces on contact terminal pads (e.g., contact terminal pads 114) via a de-flashing process. At 712, channels (e.g., micro-etched channels 106) are etched (e.g., via laser ablation) into a bottom surface (e.g., bottom surface 108) of the IC package. Specifically, the channels are etched into a bottom surface of the mold compound and around a periphery of contact terminal pads of the lead frame such that a portion of the mold compound is etched and a portion of the contact terminal pads is etched. At 714, after a singulation process (e.g., dicing, sawing, cutting with a laser, etc.), the IC package is mounted to a printed circuit board (e.g., printed circuit board (PCB) 104) via a solder process (e.g., solder past printing). At 716, an under-fill material (e.g., under-fill material 110) is injected (e.g., via a jet dispensing process) between the bottom of the IC package and the PCB. The under-fill material is injected such that the under-fill material fills the micro-etched channels.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An integrated circuit comprising:
a lead frame having electrically conductive contact terminal pads;
a die centrally disposed in the lead frame;
wire bonds electrically connecting the die to the electrically conductive terminal pads;
a mold compound encapsulating the die and the wire bonds, a bottom surface of the mold compound being substantially flush with a bottom surface of the contact terminal pads; and
a channel defined in the bottom surface of the mold compound around a periphery of the contact terminal pads.

2. The integrated circuit of claim 1, wherein the channel overlaps the mold compound and the contact terminal pads.

3. The integrated circuit of claim 1, wherein the channel has a height in a range of 40-50um and a width in a range of 55-75um.

4. The integrated circuit of claim 3, wherein the width of the channel overlaps the contact terminal pads in a range of 15-25um and overlaps the mold compound adjacent to the contact terminal pads in a range of 40-50um.

5. The integrated circuit of claim 1, wherein the channel is filled with an under-fill material to relieve stress between the integrated circuit and a printed circuit board due to a coefficient of thermal expansion mismatch between the mold compound and the printed circuit board during a curing process.

6. The integrated circuit of claim 1, further comprising a lead lock to bond the lead frame to the mold compound.

7. The integrated circuit of claim 6, wherein the lead lock has a thickness of approximately 100um.

8. The integrated circuit of claim 1, further comprising a die pad having an exposed pad that may or may not be flush with a bottom surface of the mold compound to dissipate heat from the integrated circuit, wherein the die is attached to a top planar surface of the die pad via a die attach.

9. An electronic device assembly comprising:
a printed circuit board;
an integrated circuit attached to the printed circuit board, the integrated circuit including:
a lead frame having electrically conductive contact terminal pads;
a die centrally disposed in the lead frame;
wire bonds electrically connecting the die to the electrically conductive terminal pads;
a mold compound encapsulating the die and the wire bonds, a bottom surface of the mold compound being flush with a bottom surface of the contact terminal pads; and
a channel defined in the bottom surface of the mold compound around a periphery of the contact terminal pads; and
an under-fill material disposed between the bottom surface of the mold compound and a top surface of the printed circuit board, wherein the under-fill material is disposed in the channels.

10. The electronic device assembly of claim 9, wherein the channel overlaps the mold compound and the contact terminal pads.

11. The electronic device assembly of claim 9, wherein the under-fill material is configured to relieve stress between the integrated circuit and the printed circuit board due to a coefficient of thermal expansion mismatch between the mold compound and the printed circuit board during a curing process.

12. The electronic device assembly of claim 9, wherein the printed circuit board is a printed circuit board.

13. The electronic device assembly of claim 9, wherein the channel has a height in a range of 40-50um and a width in a range of 55-75um.

14. The electronic device assembly of claim 13, wherein the width of the channel overlaps the contact terminal pads in a range of 15-25um and overlaps the mold compound adjacent to the contact terminal pads in a range of 40-50um.

15. The electronic device assembly of claim 9, wherein the integrated circuit further comprises a die pad having an exposed pad that may or may not be flush with a bottom surface of the mold compound to dissipate heat from the integrated circuit, wherein the die is attached to a top planar surface of the die pad via a die attach.

16. The electronic device assembly of claim 9, further comprising a lead lock to secure the lead frame to the mold compound.

17. The electronic device assembly of claim 16, wherein the lead lock has a thickness of approximately 100um.

18. A method comprising:
providing a lead frame having leads and a die pad, the die pad being centrally disposed in the lead frame;
attaching a die to a top planar surface of the die pad via a die attach;
attaching wire bonds from the die to the leads;
forming a mold compound over the lead frame, the die, and the wire bonds to form an integrated circuit, the leads having contact terminal pads exposed on a bottom surface of the mold compound, wherein the contact terminal pads are substantially flush with the bottom surface of the mold compound; and
etching a channel on the bottom surface of the mold compound and around a periphery of the contact terminal pads, the channels configured to receive an under-fill material.

19. The method of claim 18, wherein etching the channel on the bottom surface of the mold compound and around the periphery of the contact terminal pads includes etching a portion of the mold compound and a portion of the contact terminal pads, wherein a width of the etched portion of the mold compound is greater than a width of the etched portion of the contact terminal pads.

20. The method of claim 18, further comprising mounting the integrated circuit to a printed circuit board.

21. The method of claim 20, further comprising injecting the under-fill material between the bottom surface of the mold compound and the printed circuit board, wherein the under-fill material fills the channels on the bottom surface of the mold compound, the under-fill material configured to relieve stress between the integrated circuit and the printed circuit board due to a coefficient of thermal expansion mismatch between the mold compound and the printed circuit board during a curing process.

22. The method of claim 18, wherein the channel overlaps the mold compound and the contact terminal pads.
